(19) United States
(12) Patent Application Publication
(10) Pub. No.: US 2011/0068406 A1
(43) Pub. Date: Mar. 24, 2011

(54) SEMICONDUCTOR DEVICE

(75) Inventors: Norio YASUHARA, Kanagawa-ken (JP); Kumiko SATO, Kanagawa-ken (JP)

(73) Assignee: Kabushiki Kaisha Toshiba, Tokyo (JP)

(21) Appl. No.: 12/878,948

(22) Filed: Sep. 9, 2010

(30) Foreign Application Priority Data
Sep. 24, 2009 (JP) 2009-218762

(51) Int. Cl. H01L 29/78

(52) U.S. Cl. 257/367; 257/288; 257/E29.255

(57) ABSTRACT

According to one embodiment, a semiconductor device includes a semiconductor layer of a first conductivity type, a first source portion, a second source portion, a drain portion, a first main electrode, a second main electrode, and a gate electrode. The first source portion includes a first source contact region of a second conductivity type and a back gate contact region of the first conductivity type. The drain portion includes a drain contact region of the second conductivity type, a first drift region of the second conductivity type, and a second drift region of the second conductivity type. When a reverse bias is applied to p-n junction between the semiconductor layer and the drain portion, avalanche breakdown is more likely to occur near the first drift region than near the second drift region.

### CROSS-REFERENCE TO RELATED APPLICATION

This application is based upon and claims the benefit of priority from Japanese Patent Application No. 2009-218762, filed on Sep. 24, 2009; the entire contents of which are incorporated herein by reference.

### FIELD

Embodiments described herein relate generally to a semiconductor device.

### BACKGROUND

In a DC-DC converter with a relatively low input voltage of e.g. approximately 5 V, an integrated circuit (IC) is increasingly used for downsizing. The integrated circuit (IC) integrates output power devices and a control circuit. The voltages applied to the power devices may jump significantly due to parasitic inductance and cause avalanche breakdown in the power devices. Hence, it is desirable for the power devices to have sufficient avalanche withstand capability. Thus, a structure in which a p⁺-type region (in the case of an N channel MOSFET) connected to the source electrode is formed adjacent to the source region, is proposed.

It is desirable that the ON resistance of the power devices is as low as possible for a higher efficiency of the DC-DC converter. However, if the p⁺-type region is formed in the source formation region to achieve high avalanche withstand capability, the specific ON resistance (i.e. ON resistance for unit device area) unfortunately increases.

### BRIEF DESCRIPTION OF THE DRAWINGS

FIG. 1 is a schematic view showing a planar layout of major components in a semiconductor device according to a first embodiment;

FIG. 2 is a cross-sectional view along A-A′ in FIG. 1;

FIG. 3 is a schematic view showing a planar layout of major components in a semiconductor device according to a second embodiment;

FIG. 4 is a cross-sectional view along B-B′ in FIG. 3;

FIG. 5 is a schematic view showing a planar layout of major components in a semiconductor device according to a third embodiment;

FIG. 6 is a cross-sectional view along C-C′ in FIG. 5;

FIG. 7 is a cross-sectional view along D-D′ in FIG. 5; and

FIG. 8 is a schematic cross-sectional view of a semiconductor device according to a fourth embodiment.

### DETAILED DESCRIPTION

According to one embodiment, a semiconductor device includes a semiconductor layer of a first conductivity type, a first source portion, a second source portion, a drain portion, a first main electrode, a second main electrode, a gate insulating film and a gate electrode. The first source portion includes a first source contact region of a second conductivity type and a back gate contact region of the first conductivity type. The first source contact region is formed in a surface of the semiconductor layer. The back gate contact region is formed in the surface of the semiconductor layer adjacent to the first source contact region. The second source portion includes a second source contact region of the second conductivity type. The second source contact region is formed in the surface of the semiconductor layer separately from the first source portion. The drain portion includes a drain contact region of the second conductivity type, a first drift region of the second conductivity type, and a second drift region of the second conductivity type. The drain contact region is formed in the surface of the semiconductor layer separately from the first source portion and the second source portion. The first drift region is formed adjacent to the drain contact region in the surface of the semiconductor layer between the drain contact region and the first source contact region. The first drift region has a second conductivity type impurity concentration lower than a second conductivity type impurity concentration of the drain contact region. The second drift region is formed adjacent to the drain contact region in the surface of the semiconductor layer between the drain contact region and the second source contact region. The second drift region has a second conductivity type impurity concentration lower than the second conductivity type impurity concentration of the drain contact region. The first main electrode is electrically connected to the drain contact region. The second main electrode is electrically connected to the first source contact region, the back gate contact region, and the second source contact region. The gate insulating film is provided on the surface of the semiconductor layer between the first source contact region and the first drift region and on the surface of the semiconductor layer between the second source contact region and the second drift region. The gate electrode is provided on the gate insulating film. When a reverse bias is applied to p-n junction between the semiconductor layer and the drain portion, avalanche breakdown is more likely to occur near the first drift region than near the second drift region.

Embodiments will now be described with reference to the drawings. In the following description of the embodiments, the first conductivity type is p-type, and the second conductivity type is n-type. However, the embodiments are also applicable to the case where the first conductivity type is n-type and the second conductivity type is p-type. Furthermore, although silicon is used as an example of the semiconductor, semiconductors other than silicon (e.g., compound semiconductors such as SiC and GaN) may also be used.

### First Embodiment

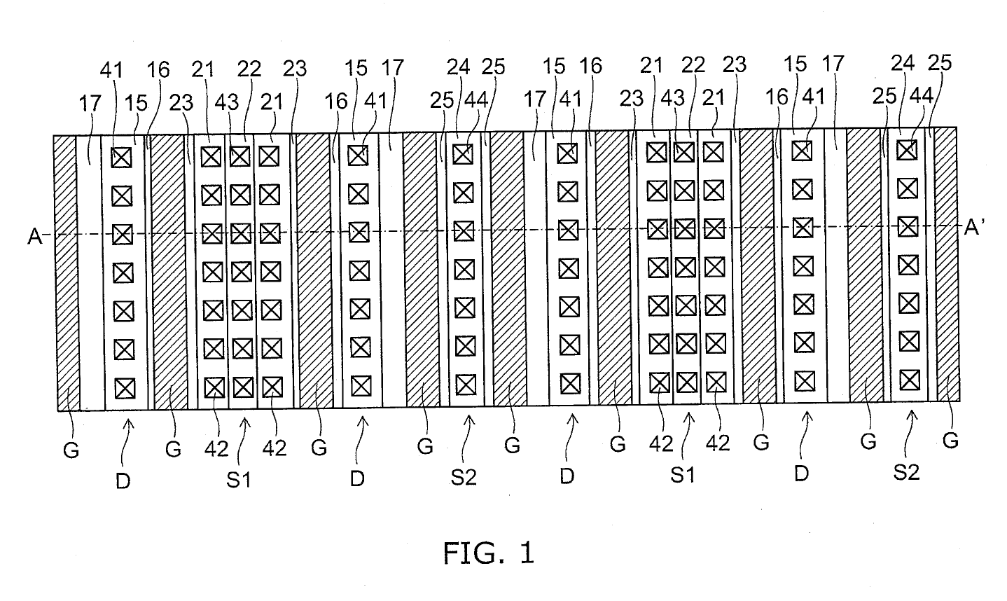

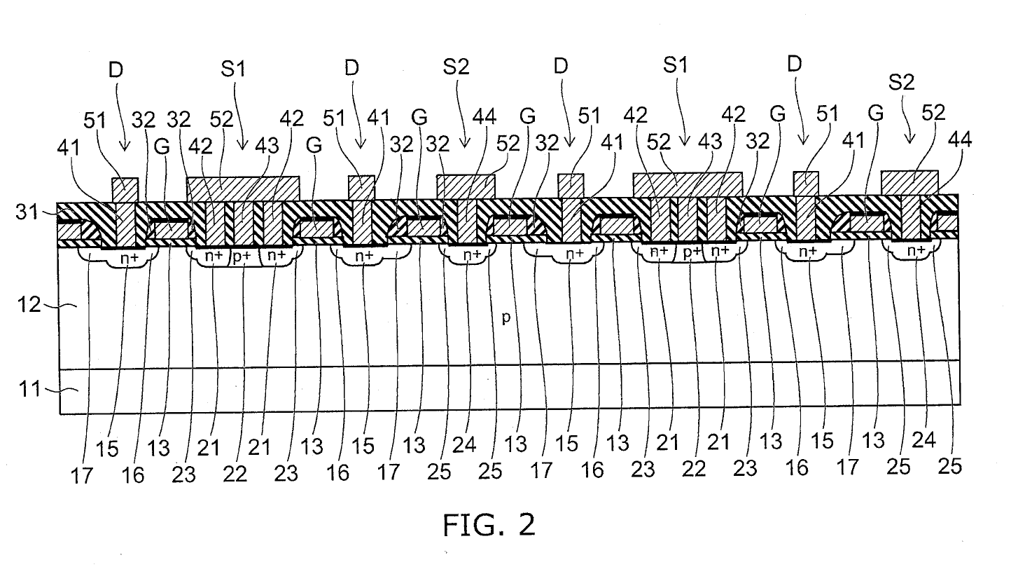

FIG. 1 is a schematic view showing a planar layout of major components in a semiconductor device according to a first embodiment. FIG. 2 is a schematic cross-sectional view corresponding to A-A′ cross section in FIG. 1. The semiconductor device according to this embodiment is a lateral semiconductor device in which main current flows in lateral direction connecting between a drain region and a source region formed in a surface of a substrate during gate-on.

As shown in FIG. 2, a first source portion S1, a second source portion S2, and a drain portion D are formed separately from each other in a surface of a p-type semiconductor layer 12. The p-type semiconductor layer 12 is illustratively a p-type well formed in a silicon substrate 11.

The first source portion S1 includes two n⁺-type first source contact regions 21, a p⁺-type back gate contact region 22, and two n-type regions 23. The n-type regions 23 have a lower n-type impurity concentration than the first source contact regions 21.

The first source contact regions 21, the back gate contact region 22, and the n-type regions 23 are formed in the surface of the p-type semiconductor layer 12. The depth of the first source contact regions 21 from the surface is nearly equal to the depth of the back gate contact region 22 from the surface. The n-type regions 23 are shallower than the first source contact region 21s and the back gate contact region 22.

As shown in FIG. 1, the first source contact regions 21, the back gate contact region 22, and the n-type regions 23 are laid out in a striped planar pattern. The back gate contact region 22 is located between a pair of first source contact regions 21 and adjacent to those first source contact regions 21. The n-type region 23 is adjacent to the first source contact region 21. The first source contact region 21 is located between the n-type region 23 and the back gate contact region 22.

The second source portion S2 includes an n⁺-type second source contact region 24 and two n-type regions 25. The n-type regions 25 have a lower n-type impurity concentration than the second source contact region 24.

The second source contact region 24 and the n-type regions 25 are formed in the surface of the p-type semiconductor layer 12. The n-type regions 25 are shallower than the second source contact region 24. The second source contact region 24 and the n-type regions 25 are laid out in a striped planar pattern. The second source contact region 24 is located between a pair of n-type regions 25 and adjacent to those n-type regions 25.

The back gate contact region 22 is not provided in the second source portion S2. Therefore, the ON resistance per unit area of the metal-oxide-semiconductor field effect transistor (MOSFET) including the second source portion S2, the drain portion D, and a gate electrode G is lower than the ON resistance per unit area of the MOSFET including the first source portion S1, the drain portion D, and a gate electrode G.

The drain portion D includes an n⁺-type drain contact region 15, an n-type first drift region 16, and an n-type second drift region 17. The n-type first drift region 16 has a lower n-type impurity concentration than the drain contact region 15. The n-type second drift region 17 also has a lower n-type impurity concentration than the drain contact region 15.

The drain contact region 15, the first drift region 16, and the second drift region 17 are formed in the surface of the p-type semiconductor layer 12. The depth of the first drift region 16 from the surface is nearly equal to the depth of the second drift region 17 from the surface. The first drift region 16 is shallower than the drain contact region 15.

The drain contact region 15, the first drift region 16, and the second drift region 17 are laid out in a striped planar pattern. The drain contact region 15 is located between the first drift region 16 and the second drift region 17. The drain contact region 15 is adjacent to the first drift region 16 and the second drift region 17. The second drift region 17 is longer in length along the channel length direction than the first drift region 16. The channel length direction is the lateral direction.

The drain portion D is formed between the first source portion S1 and the second source portion S2. That is, a plurality of first source portions S1 and second source portions S2 are alternately laid out in the channel length direction. The drain portion D is located between the first source portion S1 and the second source portion S2. The first drift region 16 is formed at the first source portion S1 side of the drain portion D, and the second drift region 17 is formed at the second source portion S2 side of the drain portion D.

The first drift region 16 and the second drift region 17 have a relatively low impurity concentration. The first drift region 16 and the second drift region 17 relieve an electric field of a depletion layer occurring near the p-n junction with the p-type semiconductor layer 12. The n-type impurity concentration in the first drift region 16 and the second drift region 17 is lower by e.g. approximately one or two orders of magnitude than the n-type impurity concentration in the drain contact region 15 and the source contact region 21, 24.

A gate insulating film 13 is provided on the surface of the p-type semiconductor layer 12 between the first source portion S1 and the drain portion D, and between the second source portion S2 and the drain portion D. A gate electrode G is provided on the gate insulating film 13. A sidewall insulating film 32 is provided on both side surfaces of the gate electrode G in the channel length direction. The sidewall insulating film 32 is provided on the gate insulating film 13 above the n-type region 23, 25, the first drift region 16, and the second drift region 17.

An interlayer insulating layer 31 is provided above the surface of the first source portion S1, the second source portion S2, and the drain portion D. Furthermore, the interlayer insulating layer 31 covers the gate insulating film 13, the gate electrode G, and the sidewall insulating film 32.

A contact hole reaching each surface of the first source portion S1, the second source portion S2, and the drain portion D is formed in the interlayer insulating layer 31. A drain contact electrode 41 is provided in the contact hole reaching the drain contact region 15. A source contact electrode 42 is provided in the contact hole reaching the first source contact region 21. A back gate contact electrode 43 is provided in the contact hole reaching the back gate contact region 22. A source contact electrode 44 is provided in the contact hole reaching the second source contact region 24.

The drain contact electrode 41 is connected to a first main electrode 51 provided on the interlayer insulating layer 31. The source contact electrodes 42, 44 and the back gate contact electrode 43 are connected to a second main electrode 52 provided on the interlayer insulating layer 31. The first main electrode 51 and the second main electrode 52 are electrically insulated from each other.

Each surface of the drain contact region 15, the first source contact regions 21, the back gate contact region 22, the second source contact region 24, and the gate electrode G is turned into a metal silicide (e.g., cobalt silicide). Hence, each resistance of the surfaces is low.

The drain contact region 15 is electrically connected to the first main electrode 51 via the drain contact electrode 41. The first source contact regions 21 and the second source contact region 24 are electrically connected to the second main electrode 52 via the source contact electrodes 42 and 44, respectively. The back gate contact region 22 is electrically connected to the second main electrode 52 via the back gate contact electrode 43. The p-type semiconductor layer 12 is supplied with a potential generally equal to the potential of the second main electrode 52 via the back gate contact electrode 43 and the back gate contact region 22. The gate electrode G is connected to a gate wiring, not shown.

In the semiconductor device according to this embodiment described above, with the first main electrode 51 placed at a higher potential relative to the second main electrode 52, the gate electrode G is applied with a desired control voltage. Then, an n-channel (inversion layer) is formed in the surface side of the p-type semiconductor layer 12 below the gate electrode G. A main current flows between the first main electrode 51 and the second main electrode 52 via the drain contact region 15, the first drift region 16, the n-channel, the n-type regions 23, and the first source contact regions 21, and via the drain contact region 15, the second drift region 17, the n-channel, the n-type regions 25, and the second source contact region 24. Thus, the semiconductor device is turned on.

The semiconductor device according to this embodiment is suitable for application to power devices for power control. A power device requires compatibility between low ON resistance and high avalanche withstand capability.

The back gate contact region 22 is not provided in the second source portion S2. Hence, the second source portion S2 has a smaller area. Thus, the MOSFET including the second source portion S2, the drain portion D, and the gate electrode G has a lower ON resistance per unit area (Ron·A) than the MOSFET including the first source portion S1, the drain portion D, and the gate electrode G. However, the avalanche withstand capability achieved only by the second source portion S2 is low, and there is concern that avalanche breakdown therein results in destroying the device. Thus, the first source portion S1 is provided besides the second source portion S2. The first source portion S1 has a high avalanche withstand capability because the first source portion S1 includes a p⁺-type back gate contact region 22.

Hence, in this embodiment, avalanche breakdown is made more likely to occur at the side of the first source portion S1 having a structure with higher avalanche withstand capability. Specifically, the first drift region 16 formed at the first source portion S1 side is made shorter in length along the channel length direction than the second drift region 17 formed at the second source portion S2 side.

When the first main electrode 51 is placed at a higher potential relative to the second main electrode 52, a reverse bias is applied to the p-n junction between the p-type semiconductor layer 12 and the regions of n-type in the drain portion D (drain contact region 15, first drift region 16, and second drift region 17) on the high potential side, and a depletion layer extends from the p-n junction. At this time, because the first drift region 16 has a shorter length than the second drift region 17, the p-n junction between the first drift region 16 and the p-type semiconductor layer 12 is applied with a higher electric field, and avalanche breakdown is more likely to occur near that portion.

The p⁺-type back gate contact region 22 is formed near this avalanche breakdown point. Hence, carriers (holes) generated by avalanche breakdown are ejected via the back gate contact region 22 to the second main electrode 52. This can prevent device destruction due to avalanche breakdown.

Here, the size and impurity concentration of various elements are designed so that the current is at most of the order of e.g. the current releasing the energy accumulated in the parasitic inductance and does not lead to device destruction even if avalanche breakdown occurs.

As described above, the device of this embodiment has a first source portion S1 including a back gate contact region 22, and a second source portion S2 including no back gate contact region 22. Furthermore, avalanche breakdown is more likely to occur on the first source portion S1 side of the drift region of the drain portion D. Thus, a structure with low ON resistance and high avalanche withstand capability can be achieved on average throughout the device.

In the foregoing, the first source portions S1 and the second source portions S2 are alternately laid out with the drain portion D located between the first source portions S1 and the second source portions S2. However, the layout is not limited thereto. For instance, there may be a region where a plurality of first source portions 51 are consecutively formed. However, it is not very desirable to consecutively form a plurality of second source portions S2 including no back gate contact region 22, because of concern about the decrease of avalanche withstand capability.

By alternately laying out the first source portions S1 and the second source portions S2 with the drain portion D located between the first source portions S1 and the second source portions S2, it is possible to avoid local occurrences of low avalanche withstand capability or high ON resistance in the surface direction of the device. Thus, high avalanche withstand capability and low ON resistance can be achieved on average throughout the device.

Next, a method for manufacturing a semiconductor device according to this embodiment is described.

First, the p-type semiconductor layer 12 is formed in the surface side of the substrate 11. Subsequently, the gate insulating film 13 is formed above the surface of the p-type semiconductor layer 12. Furthermore, the gate electrode G is formed above the gate insulating film 13. The patterned gate electrode G is used as a mask to perform ion implantation of n-type impurity after the gate electrode G is patterned. Thus, n-type regions to constitute the n-type region 23, 25, the first drift region 16, and the second drift region 17 are formed at a shallow position.

Subsequently, the sidewall insulating film 32 is formed on the side surface of the gate electrode G. At this time, the lateral thickness of the sidewall insulating film 32 to be provided above the second drift region 17 is made thicker than the lateral thickness of the sidewall insulating film 32 to be provided above the first drift region 16.

Then, the sidewall insulating film 32 and the gate electrode G are used as a mask to perform ion implantation of n-type impurity. Thus, the drain contact region 15, the first source contact regions 21, and the second source contact region 24 are formed. Furthermore, ion implantation of p-type impurity is performed to form the back gate contact region 22. Thus, a difference in length occurs between the first drift region 16 and the second drift region 17 below the sidewall insulating film 32 in accordance with the lateral thickness of the sidewall insulating film 32 in a self-aligned manner.

Subsequently, metal silicidation is formed on the surface of the drain contact region 15, the surface of the first source contact region 21, the surface the second source contact region 24, the surface of the back gate contact region 22, and the surface of the gate electrode G. The interlayer insulating layer 31 is formed. And the contact electrodes 41-44, the first main electrode 51 and the second main electrode 52 are formed.

### Second Embodiment

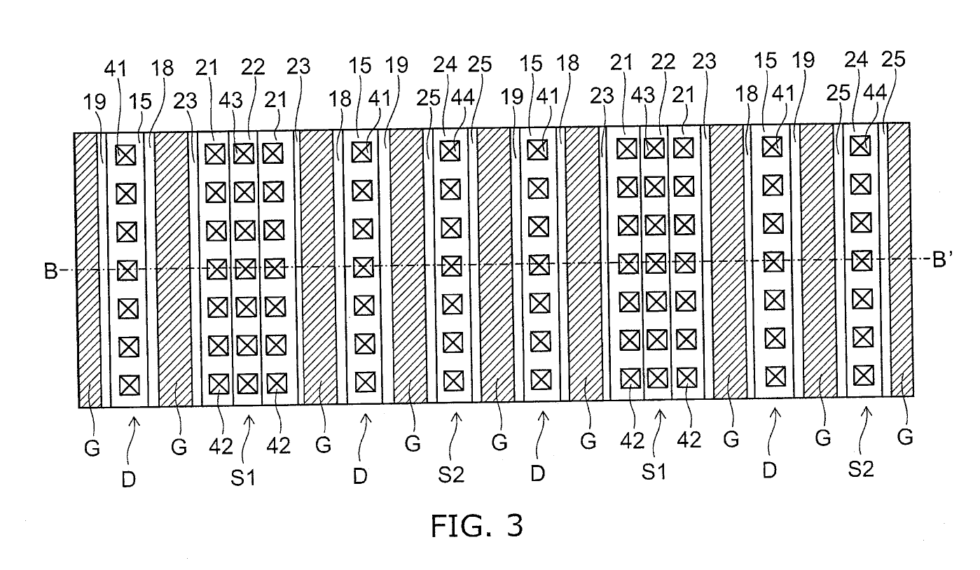

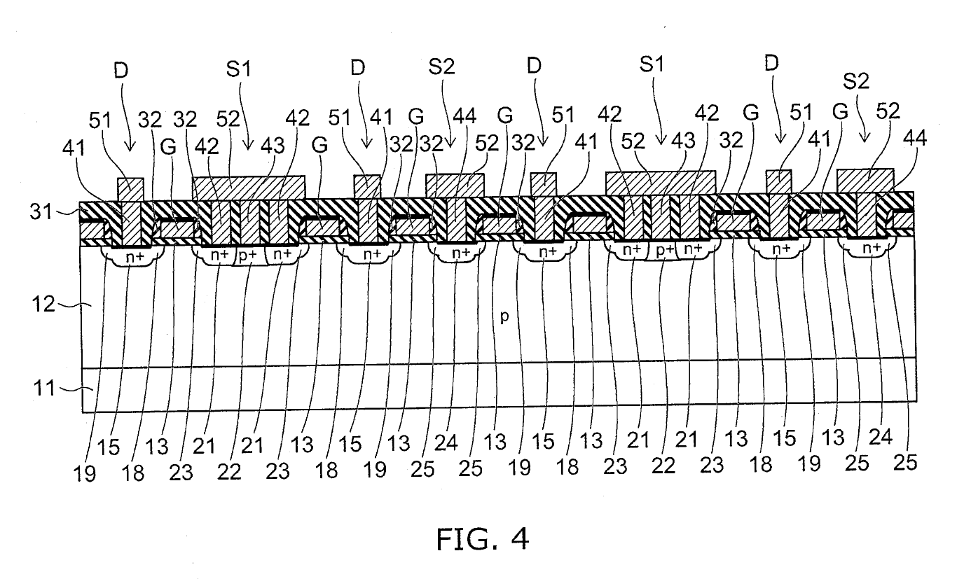

FIG. 3 is a schematic view showing a planar layout of major components in a semiconductor device according to a second embodiment. FIG. 4 is a schematic cross-sectional view corresponding to B-B′ cross section in FIG. 3. The same components as those in the above first embodiment are labeled with like reference numerals.

This embodiment is different from the above first embodiment in the configuration of the first drift region 18 and the second drift region 19 in the drain portion D.

The drain portion D includes an n⁺-type drain contact region 15, an n-type first drift region 18, and an n-type second drift region 19. The n-type first drift region 18 has a lower n-type impurity concentration than the drain contact region 15. The n-type second drift region 19 also has a lower n-type impurity concentration than the drain contact region 15.

The length along the channel length direction of the first drift region 18 is nearly equal to the length along the channel length direction of the second drift region 19. However, the first drift region 18 has a higher n-type impurity concentration than the second drift region 19. The n-type impurity concentration in the first drift region 18 is lower than the n-type impurity concentration in the drain contact region 15. For instance, the dose amount of n-type impurity to constitute a first drift region 18 is made higher than the dose amount of n-type impurity to constitute a second drift region 19.

In this embodiment, the first drift region 18 formed at the first source portion S1 side is made higher in n-type impurity concentration than the second drift region 19 formed at the second source portion S2 side. Thus, avalanche breakdown is made more likely to occur on the side of the first source portion S1 having a structure with higher avalanche withstand capability.

More specifically, the p-n junction between the first drift region 18 and the p-type semiconductor layer 12 is applied with a higher electric field, and avalanche breakdown is more likely to occur near that portion because the first drift region 18 is higher in n-type impurity concentration than the second drift region 19. The p⁺-type back gate contact region 22 is formed near the avalanche breakdown point. Hence, carriers (holes) generated by avalanche breakdown are ejected via the back gate contact region 22 to the second main electrode 52. This can prevent device destruction due to avalanche breakdown.

Thus, the device of this embodiment also has a first source portion S1 including a back gate contact region 22, and a second source portion S2 including no back gate contact region 22. Furthermore, avalanche breakdown is more likely to occur on the first source portion S1 side of the drift region of the drain portion D. Thus, a structure with low ON resistance and high avalanche withstand capability can be achieved on average throughout the device.

In addition, the first embodiment and the second embodiment may be combined with each other. That is, the length along the channel length direction of the first drift region formed at the first source portion S1 side is shorter than the length along the channel length direction of the second drift region formed at the second source portion S2 side. And the n-type impurity concentration of the first drift region is higher than the n-type impurity concentration of the second drift region. Thus, avalanche breakdown may be made more likely to occur at the first source portion S1 side.

### Third Embodiment

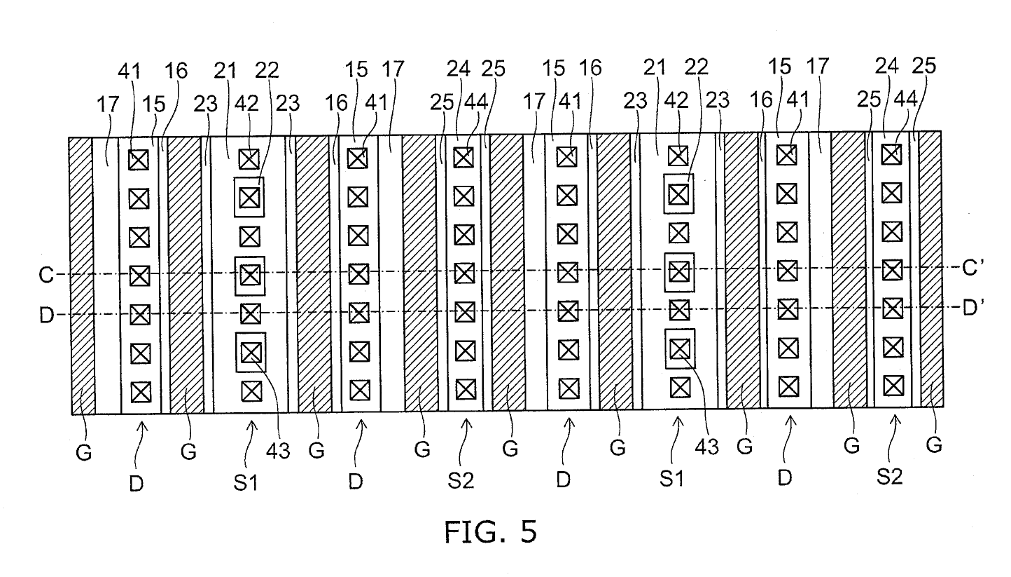

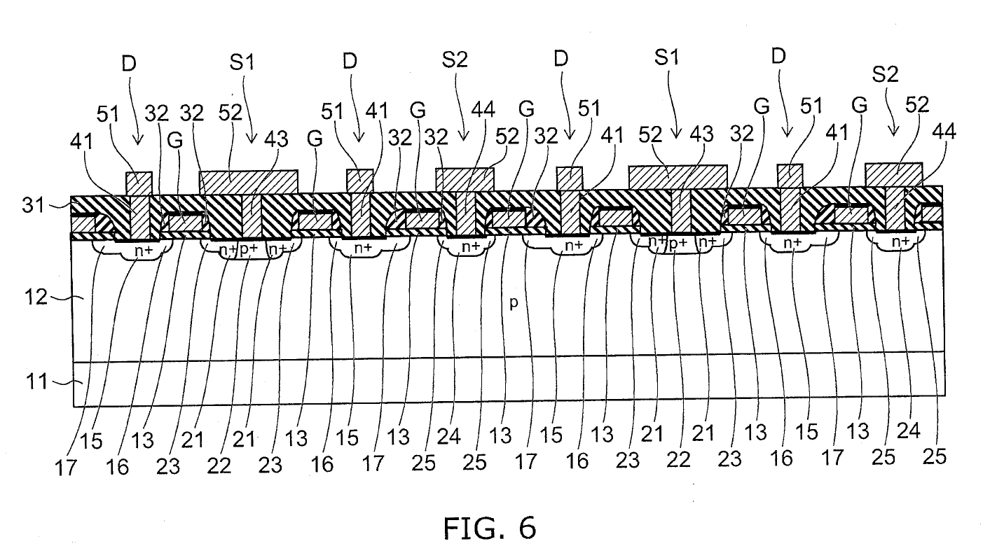

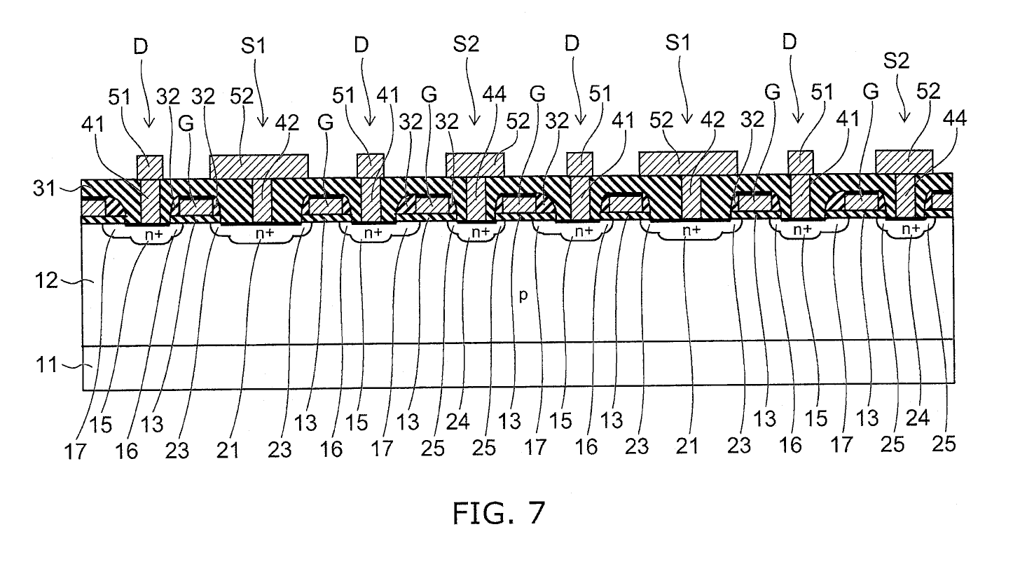

FIG. 5 is a schematic view showing a planar layout of major components in a semiconductor device according to a third embodiment. FIG. 6 is a schematic cross-sectional view corresponding to C-C′ cross section in FIG. 5. FIG. 7 is a schematic cross-sectional view corresponding to D-D′ cross section in FIG. 5. The same components as those in the above embodiments are labeled with like reference numerals.

This embodiment is different from the above embodiments in the planar layout of the first source contact region 21 and the back gate contact region 22 in the first source portion S1.

As shown in FIG. 5, the back gate contact region 22 is selectively formed, surrounded by the first source contact region 21. The first source contact regions 21 and the back gate contact regions 22 are alternately laid out in channel width direction. The channel width direction is direction orthogonal to the channel length direction.

This layout can make the area of the first source portion S1 smaller than the striped layout as in the first and second embodiment. Hence, this layout is more favorable to reducing ON resistance per unit area.

Here, the striped layout of the first source contact region 21 and the back gate contact region 22 as in the first and second embodiments has a lower ON resistance per unit channel width than the layout of the third embodiment. Thus, the first and second embodiments can reduce the gate capacitance, and are suitable for high frequency switching applications.

Also in this embodiment, the first drift region 16 formed at the first source portion S1 side is made shorter in length along the channel length direction than the second drift region 17 formed at the second source portion S2 side, as in the first embodiment. Thus, avalanche breakdown is made more likely to occur at the side of the first source portion S1 having a structure with higher avalanche withstand capability.

Thus, the device of the embodiment also has a first source portion S1 including a back gate contact region 22, and a second source portion S2 including no back gate contact region 22. Furthermore, avalanche breakdown is more likely to occur at the first source portion S1 side of the drift region of the drain portion D. Thus, a structure with low ON resistance and high avalanche withstand capability can be achieved on average throughout the device.

In addition, avalanche breakdown may be made more likely to occur at the first source portion S1 side by making the first drift region formed at the first source portion S1 side higher in n-type impurity concentration than the second drift region formed at the second source portion S2 side, as in the second embodiment. Avalanche breakdown may be made more likely to occur at the first source portion S1 side by making the first drift region shorter in length along the channel length direction and higher in n-type impurity concentration than the second drift region.

### Fourth Embodiment

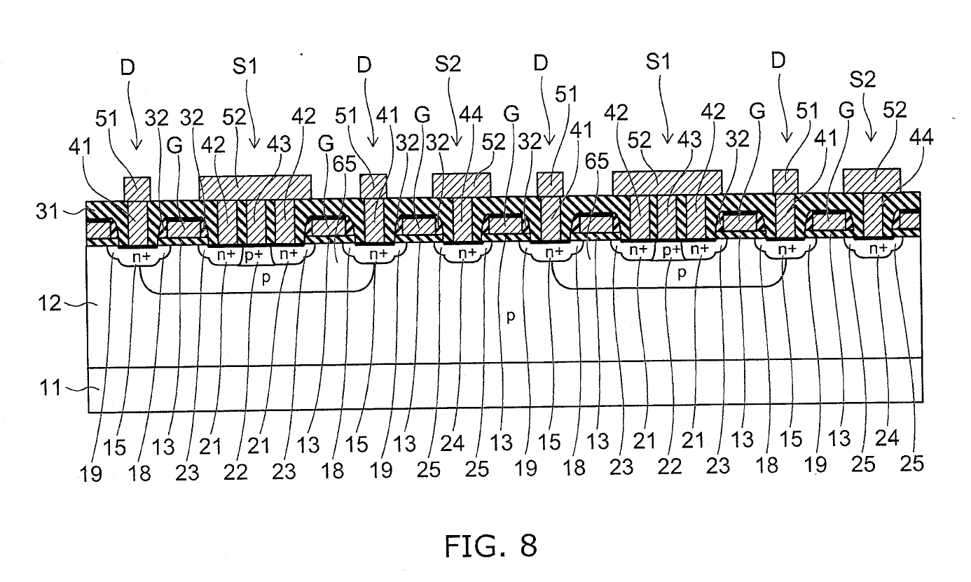

FIG. 8 is a schematic cross-sectional view of a semiconductor, device according to a fourth embodiment. The same components as those in the above embodiments are labeled with like reference numerals.

In this embodiment, a p-type well 65 having a higher p-type impurity concentration than the p-type semiconductor layer 12 is formed in the surface side of the p-type semiconductor layer 12. The first source contact regions 21, the back gate contact region 22, the n-type regions 23, and the first drift region 18 are formed in the surface of the p-type well 65.

The p-type well 65 is not formed near the second drift region 19. Hence, avalanche breakdown is more likely to occur at the side of the first drift region 18. Thus, the device of the embodiment also has a first source portion S1 including a back gate contact region 22, and a second source portion S2 including no back gate contact region 22. Furthermore, avalanche breakdown is more likely to occur at the first source portion S1 side of the drift region of the drain portion D. Thus, a structure with low ON resistance and high avalanche withstand capability can be achieved on average throughout the device.

Furthermore, in this embodiment, the p-type well 65 having a higher p-type impurity concentration than the p-type semiconductor layer 12 is formed in the ejection path through which holes generated by avalanche breakdown are led to the back gate contact region 22. This serves to reduce the ejection resistance of holes, facilitate hole ejection, and improve avalanche withstand capability.

In addition, the fourth embodiment can be combined with the first and/or second embodiment. That is, in the structure shown in FIG. 8, the first drift region 18 formed at the first source portion S1 side may be made shorter in length along the channel length direction than the second drift region 19 formed at the second source portion S2 side. Furthermore, the first drift region 18 may be made higher in n-type impurity concentration. Furthermore, the first drift region 18 may be made shorter in length along the channel length direction and higher in n-type impurity concentration.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A semiconductor device comprising:
a semiconductor layer of a first conductivity type;
a first source portion including a first source contact region of a second conductivity type formed in a surface of the semiconductor layer, and a back gate contact region of the first conductivity type formed in the surface of the semiconductor layer adjacent to the first source contact region;
a second source portion including a second source contact region of the second conductivity type formed in the surface of the semiconductor layer separately from the first source portion;
a drain portion including a drain contact region of the second conductivity type formed in the surface of the semiconductor layer separately from the first source portion and the second source portion, a first drift region of the second conductivity type formed adjacent to the drain contact region in the surface of the semiconductor layer between the drain contact region and the first source contact region, the first drift region having a second conductivity type impurity concentration lower than a second conductivity type impurity concentration of the drain contact region, and a second drift region of the second conductivity type formed adjacent to the drain contact region in the surface of the semiconductor layer between the drain contact region and the second source contact region, the second drift region having a second conductivity type impurity concentration lower than the second conductivity type impurity concentration of the drain contact region;
a first main electrode electrically connected to the drain contact region;
a second main electrode electrically connected to the first source contact region, the back gate contact region, and the second source contact region;
a gate insulating film provided on the surface of the semiconductor layer between the first source contact region and the first drift region and on the surface of the semiconductor layer between the second source contact region and the second drift region; and
a gate electrode provided on the gate insulating film,
when a reverse bias is applied to p-n junction between the semiconductor layer and the drain portion, avalanche breakdown being more likely to occur near the first drift region than near the second drift region.

2. The device according to claim 1, wherein a length along channel length direction of the second drift region is longer than a length along the channel length direction of the first drift region.

3. The device according to claim 1, wherein the second conductivity type impurity concentration of the first drift region is higher than the second conductivity type impurity concentration of the second drift region.

4. The device according to claim 1, wherein
a length along channel length direction of the second drift region is longer than a length along the channel length direction of the first drift region, and
the second conductivity type impurity concentration of the first drift region is higher than the second conductivity type impurity concentration of the second drift region.

5. A semiconductor device comprising:
a semiconductor layer of a first conductivity type;
a first source portion including a first source contact region of a second conductivity type formed in a surface of the semiconductor layer, and a back gate contact region of the first conductivity type formed in the surface of the semiconductor layer adjacent to the first source contact region;
a second source portion including a second source contact region of the second conductivity type formed in the surface of the semiconductor layer separately from the first source portion;
a drain portion including a drain contact region of the second conductivity type formed in the surface of the semiconductor layer separately from the first source portion and the second source portion, a first drift region of the second conductivity type formed adjacent to the drain contact region in the surface of the semiconductor layer between the drain contact region and the first source contact region, the first drift region having a second conductivity type impurity concentration lower than a second conductivity type impurity concentration of the drain contact region, and a second drift region of the second conductivity type formed adjacent to the drain contact region in the surface of the semiconductor layer between the drain contact region and the second source contact region, the second drift region having a second conductivity type impurity concentration lower than the second conductivity type impurity concentration of the drain contact region and a length along channel length direction longer than a length along the channel length direction of the first drift region;
a first main electrode electrically connected to the drain contact region;
a second main electrode electrically connected to the first source contact region, the back gate contact region, and the second source contact region;
a gate insulating film provided on the surface of the semiconductor layer between the first source contact region and the first drift region and on the surface of the semiconductor layer between the second source contact region and the second drift region; and
a gate electrode provided on the gate insulating film.

6. The device according to claim 5, wherein the second conductivity type impurity concentration of the first drift region is higher than the second conductivity type impurity concentration of the second drift region.

7. A semiconductor device comprising:
a semiconductor layer of a first conductivity type;
a first source portion including a first source contact region of a second conductivity type formed in a surface of the semiconductor layer, and a back gate contact region of the first conductivity type formed in the surface of the semiconductor layer adjacent to the first source contact region;
a second source portion including a second source contact region of the second conductivity type formed in the surface of the semiconductor layer separately from the first source portion;
a drain portion including a drain contact region of the second conductivity type formed in the surface of the semiconductor layer separately from the first source portion and the second source portion, a first drift region of the second conductivity type formed adjacent to the drain contact region in the surface of the semiconductor layer between the drain contact region and the first source contact region, the first drift region having a second conductivity type impurity concentration lower than a second conductivity type impurity concentration of the drain contact region, and a second drift region of the second conductivity type formed adjacent to the drain contact region in the surface of the semiconductor layer between the drain contact region and the second source contact region, the second drift region having a second conductivity type impurity concentration lower than the second conductivity type impurity concentration of the drain contact region and the first drift region;
a first main electrode electrically connected to the drain contact region;
a second main electrode electrically connected to the first source contact region, the back gate contact region, and the second source contact region;
a gate insulating film provided on the surface of the semiconductor layer between the first source contact region and the first drift region and on the surface of the semiconductor layer between the second source contact region and the second drift region; and
a gate electrode provided on the gate insulating film.

8. The device according to claim 1, further comprising:
a well of the first conductivity type formed in a surface side of the semiconductor layer and having a first conductivity type impurity concentration higher than a first conductivity type impurity concentration of the semiconductor layer,
the first source contact region, the back gate contact region, and the first drift region being formed in a surface of the well.

9. The device according to claim 1, wherein the first source portion and the second source portion are multiply provided and alternately laid out in channel length direction, the drain portion being sandwiched between each of the first source portions and each of the second source portions.

10. The device according to claim 1, wherein the first source contact region and the back gate contact region are formed in a striped planar pattern, and the first source contact region is provided on both sides of the back gate contact region to sandwich the back gate contact region.

11. The device according to claim 1, wherein the first source contact region and the back gate contact region are alternately formed in channel width direction.

12. The device according to claim 1, wherein a metal-oxide-semiconductor field effect transistor (MOSFET) including the second source portion, the drain portion, and the gate electrode has an ON resistance per unit area lower than an ON resistance per unit area of a MOSFET including the first source portion, the drain portion, and the gate electrode.

13. The device according to claim 1, wherein the second source portion does not include the back gate contact region and has an area smaller than an area of the first source portion.
